(19) United States
(12) Patent Application Publication
(10) Pub. No.: US 2026/0008065 A1
(43) Pub. Date: Jan. 8, 2026

(54) APPARATUS AND METHOD FOR MANUFACTURING DISPLAY DEVICE

(71) Applicant: Samsung Display Co., LTD., Yongin-si (KR)

(72) Inventor: DAEWOONG LEE, Yongin-si (KR)

(21) Appl. No.: 19/078,838

(22) Filed: Mar. 13, 2025

(30) Foreign Application Priority Data
Jul. 5, 2024 (KR) 10-2024-0088996

(51) Int. Cl. B05B 1/02; H10K 71/12

(52) U.S. Cl. CPC B05B 1/02; H10K 71/12

(57) ABSTRACT

A display device manufacturing apparatus includes a deposition source that accommodates a deposition material and has a central area facing a substrate, and a first outer area and a second outer area disposed on both sides of the central area, and a nozzle unit disposed on at least one of the first outer area and the second outer area, and having an inclination toward the central area.

This application claims priority to Korean Patent Application No. 10-2024-0088996, filed on Jul. 5, 2024, and all the benefits accruing therefrom under 35 U.S.C. § 119, the content of which in its entirety is herein incorporated by reference.

### BACKGROUND

### 1. Field

The invention relates generally to an apparatus, and more particularly to an apparatus and method for manufacturing a display device.

### 2. Description of the Related Art

Electronic devices have been widely used and are used in a variety of ways, such as mobile electronic devices and stationary electronic devices, where the electronic devices include display devices that may provide visual information such as images or videos to users to support various functions.

A display device is a device that visually displays data, and that may be formed by depositing various layers such as an organic layer, a metal layer, etc. A display device manufacturing apparatus may be used to form a plurality of layers of the display device. A display device manufacturing apparatus is used to spray a deposition material from a deposition source and deposit the deposition material on a substrate via a mask.

### SUMMARY

According to an embodiment, provided are an apparatus and method for manufacturing a display device, allowing a deposition material to be effectively sprayed.

Additional aspects will be set forth in part in the description which follows and, in part, will be apparent from the description, or may be learned by practice of the presented embodiments of the disclosure.

According to an embodiment, a display device manufacturing apparatus includes a deposition source that accommodates a deposition material and has a central area facing a substrate, and a first outer area and a second outer area on both sides of the central area, and a nozzle unit disposed on at least one of the first outer area and the second outer area, and having an inclination with respect to the central area.

In an embodiment, the nozzle unit may include a first spray nozzle having an inclination toward a front portion of a direction in which the deposition source moves, and a second spray nozzle having an inclination toward a rear portion of the direction in which the deposition source moves.

In an embodiment, in the nozzle unit, the first spray nozzle and the second spray nozzle may be alternately arranged with a preset interval therebetween in a lengthwise direction of the deposition source.

In an embodiment, in the nozzle unit, the first spray nozzle and the second spray nozzle may be arranged parallel to each other in a width direction of the deposition source.

In an embodiment, the first spray nozzle may have an inclination angle ranging from about 30° to about 75° toward the front portion in the lengthwise direction of the deposition source.

In an embodiment, the second spray nozzle may have an inclination angle ranging from about 30° to about 75° toward the rear portion in the lengthwise direction of the deposition source.

In an embodiment, the nozzle unit may have an inclination ranging from about 30° to 75° toward the substrate on a surface of the deposition source.

In an embodiment, the nozzle unit deposits the deposition material on an area of the substrate, which is adjacent to the second outer area, from the nozzle arranged in the first outer area, and deposits the deposition material on an area of the substrate, which is adjacent to the first outer area, from the nozzle arranged in the second outer area.

In an embodiment, the deposition source may have a non-spray area in the central area.

In an embodiment, a plurality of nozzles in the nozzle unit may deposit the deposition material on the substrate in inclined directions between the lengthwise direction and the width direction of the substrate.

In an embodiment, the deposition source may have the central area above which the substrate is disposed and may linearly move along the lengthwise direction of the substrate.

According to another embodiment, a display device manufacturing method includes preparing a deposition source having a central area, and nozzle units disposed on a first outer area and a second outer area arranged on both sides of the central area, placing a substrate above the central area, and depositing a deposition material on the substrate while moving the deposition source.

In an embodiment, the nozzle unit may have an inclination with respect to the central area.

In an embodiment, the deposition source may have a non-spray area in the central area.

In an embodiment, the deposition material is deposited on an area of the substrate, which is adjacent to the second outer area, from the nozzle unit arranged in the first outer area, and the deposition material is deposited on an area of the substrate, which is disposed adjacent to the first outer area, from the nozzle unit arranged in the second outer area.

In an embodiment, the nozzle unit may include a first spray nozzle having an inclination toward a front portion of a direction in which the deposition source moves, and a second spray nozzle having an inclination toward a rear portion of the direction in which the deposition source moves.

In an embodiment, the first spray nozzle may have an inclination angle ranging from about 30° to about 75° toward the front portion in the lengthwise direction of the deposition source.

In an embodiment, the second spray nozzle may have an inclination angle ranging from about 30° to about 75° toward the rear portion in the lengthwise direction of the deposition source.

In an embodiment, a plurality of nozzles in the nozzle unit may deposit the deposition material on the substrate in inclined directions between the lengthwise direction and the width direction of the substrate.

In an embodiment, the nozzle unit may have an inclination ranging from about 30° to about 75° toward the substrate on a surface of the deposition source.

### BRIEF DESCRIPTION OF THE DRAWINGS

The above and other aspects, features, and advantages of certain embodiments will be more apparent from the following description taken in conjunction with the accompanying drawings, in which:

FIG. 1 is a diagram showing an example of a display device manufacturing apparatus, according to an embodiment;

FIG. 2 is a diagram showing an example of how a deposition source of FIG. 1 moves, according to an embodiment;

FIG. 3 is a diagram showing an example of a deposition source of FIG. 2, according to an embodiment;

FIG. 4 is a diagram showing a modified example of a nozzle unit of FIG. 1, according to an embodiment;

FIG. 5 is a diagram showing a modified example of a nozzle unit of FIG. 1, according to an embodiment;

FIG. 6 is a diagram showing an example of how a deposition source moves, according to another embodiment;

FIG. 7 is a diagram showing an example of a deposition source of FIG. 6, according to an embodiment;

FIG. 8 is a diagram showing an example of a deposition source of FIG. 6, according to an embodiment;

FIG. 9 is a diagram showing a cross-section taken along line i-i′ of FIG. 8, according to an embodiment;

FIG. 10 is a diagram showing a modified example of FIG. 9, according to an embodiment;

FIG. 11 is a diagram showing a deposition source of FIG. 6, according to another embodiment;

FIG. 12 is a plan view of a display device manufactured by the display device manufacturing apparatus, according to an embodiment;

FIG. 13 is a cross-sectional view taken along line I-I′ of FIG. 6, according to an embodiment; and

FIG. 14 is a conceptional diagram showing a part of FIG. 13, according to an embodiment.

### DETAILED DESCRIPTION

Reference will now be made in detail to embodiments, examples of which are illustrated in the accompanying drawings, wherein like reference numerals refer to like elements throughout. In this regard, the invention may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

As the invention allows for various changes and numerous embodiments, particular embodiments will be illustrated in the drawings and described in detail in the written description. The attached drawings for illustrating one or more embodiments are referred to in order to gain a sufficient understanding, the merits thereof, and the objectives accomplished by the implementation. However, the invention may have different forms and should not be construed as being limited to the descriptions set forth herein.

The embodiments will be described below in more detail with reference to the accompanying drawings. Those components that are the same or are in correspondence are rendered the same reference numeral regardless of the figure number, and redundant explanations are omitted.

While such terms as “first,” “second,” etc., may be used to describe various components, such components are not be limited to the above terms. The above terms are used only to distinguish one component from another.

An expression used in the singular encompasses the expression of the plural, unless it has a clearly different meaning in the context.

In the present specification, it is to be understood that the terms “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

It will be understood that when a layer, region, or component is referred to as being “formed on” another layer, region, or component, it may be directly or indirectly formed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the invention is not limited thereto.

In the embodiments below, when layers, areas, or elements or the like are referred to as being “connected,” it will be understood that they may be directly connected or an intervening portion may be present between layers, areas or elements. For example, when layers, areas, or elements or the like are referred to as being “electrically connected,” they may be directly electrically connected, or layers, areas or elements may be indirectly electrically connected and an intervening portion may be present. Hereinafter, embodiments of the invention will be described in detail with reference to accompanying drawings.

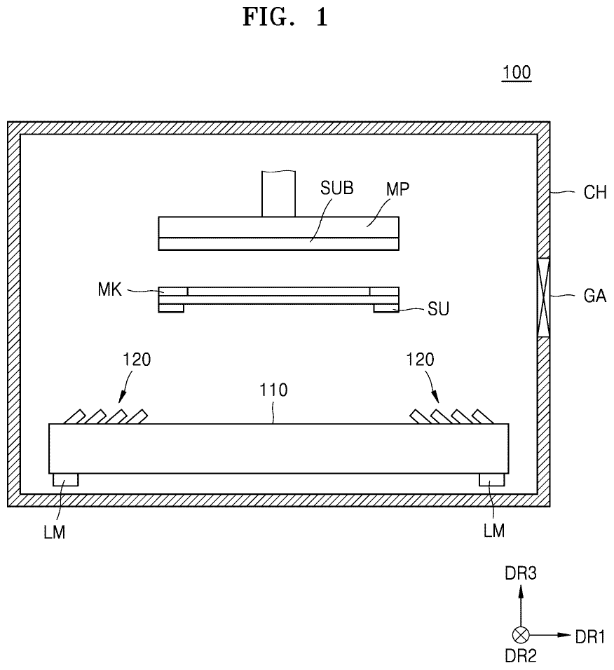

FIG. 1 is a diagram showing an example of a display device manufacturing apparatus 100, according to an embodiment.

In an embodiment and referring to FIG. 1, the display device manufacturing apparatus 100 may deposit a deposition material on a substrate SUB. For example, the substrate SUB may be a substrate of a display device. The deposition material may include an organic material. The deposition material may be deposited on the substrate SUB to form an organic light-emitting device.

Hereinafter, a first direction DR1 is defined as a lengthwise direction of a deposition source 110, a second direction DR2 is defined as a width direction of the deposition source 110, and a third direction DR3 is defined as a height direction of the deposition source 110. A plane formed when the first direction DR1 and the second direction DR2 intersect each other may be a deposition surface of the substrate SUB.

In an embodiment, the substrate SUB may have a width in the first direction DR1 and may extend in the lengthwise direction of the second direction DR2. The substrate SUB and the deposition source 110 may linearly move relative to each other in the second direction DR2, and at this time, a deposition process of the deposition source 110 may be performed.

In an embodiment, the substrate SUB may include an insulation substrate, a semiconductor substrate, a display device substrate, etc., but is not limited thereto. In an embodiment, an example in which the substrate SUB is a substrate of an organic light-emitting display device is contemplated.

In an embodiment, the structure included in the substrate SUB may vary depending on which step the applied deposition process, from among manufacturing processes of an organic light-emitting display device, corresponds to. For example, when the deposition process is a hole injection layer forming process, the substrate may be a substrate on which a pixel-defining layer and an anode electrode are formed. When the deposition process is a process for forming an organic emission layer, a target substrate may be a substrate on which a hole injection layer and/or a hole transport layer, as well as a pixel-defining layer and an anode electrode, are formed.

According to an embodiment, the display device manufacturing apparatus 100 may include a chamber CH, a moving plate MP, a mask assembly MK, and a transport portion LM. Also, the display device manufacturing apparatus 100 may include the deposition source 110 and a nozzle unit 120.

In an embodiment, the chamber CH may have a sealed space therein. The moving plate MP, the mask assembly MK, the transport portion LM, the deposition source 110, and the nozzle unit 120 may be arranged in an inner space of the chamber CH.

In an embodiment, the chamber CH may be provided with at least one gate GA. For example, the gate GA may be arranged on a side wall of the chamber CH. The gate GA may open/close the chamber CH. For example, the substrate SUB may enter and exit the chamber CH through the gate GA.

In an embodiment, the chamber CH controls a pressure of the inner space and may include a vacuum pump (not shown) and an exhaust port (not shown) for exhausting the deposition material that is not deposited on the substrate SUB.

In an embodiment, the moving plate MP may move in the chamber CH. For example, the moving plate MP may move in the first direction DR1, the second direction DR2, and the third direction DR3 while an upper portion thereof is connected to the ceiling of the chamber CH.

In an embodiment, the substrate SUB may be arranged under the moving plate MP. The moving plate MP may hold the substrate SUB by using an electrostatic force or a magnetic force. The moving plate MP may move the substrate SUB in the chamber CH.

In an embodiment, the mask assembly MK may be arranged between the substrate SUB and the deposition source 110 that is described later. The mask assembly MK may overlap the substrate SUB. The mask assembly MK may be supported by a supporter SU arranged in the chamber CH.

In an embodiment, the mask assembly MK may define a region on which a material evaporated from the deposition source 110 is deposited, and may include a mask portion and a transmission portion.

In an embodiment, the transmission portion exposes the substrate SUB so that the material evaporated from the deposition source 110 may be deposited on the exposed substrate SUB. In addition, the mask portion covers the substrate SUB and prevents the material evaporated from the deposition source 110 from being deposited on a region corresponding thereto. Therefore, the material deposited through the mask assembly MK may form a certain pattern.

In an embodiment, the transport portion LM may be disposed on the lower portion of the deposition source 110 and may move the deposition source 110 in the second direction DR2.

In an embodiment, the transport portion LM may have various components that may linearly move the deposition source 110. For example, the transport portion LM may have a rail (not shown) extending in the second direction DR2 and a driver (not shown) that moves the deposition source 110 along the rail.

In an embodiment, the deposition source 110 may be disposed below the mask assembly MK and may accommodate the deposition material therein. The deposition source 110 may vaporize or sublimate the deposition material accommodated therein and provide the deposition material to the substrate SUB.

In an embodiment, the deposition source 110 may be a linear deposition source of a line type entirely extending in the first direction DR1. The deposition source 110 may cover a width W of the substrate SUB defined in the first direction DR1. Here, the deposition source 110 covering the width W of the substrate SUB denotes that the deposition source 110 covers all of the region in the substrate SUB, on which the deposition material is deposited, in the first direction DR1, and even when the deposition source 110 does not move in the first direction DR1, the deposition may be performed on the entire deposition region located in the width direction of the substrate SUB.

In an embodiment, the deposition source 110 stores the deposition material therein and may include a heater (not shown) for heating the deposition material.

In an embodiment, the deposition material may be an organic material for an organic emission layer. For example, the deposition material may be an organic material for a hole injection layer, a hole transport layer, an electron transport layer, and an electron injection layer, but is not limited thereto, and various organic materials may be applied as the deposition material. Moreover, a plurality of different organic materials may be included in the inner space of the deposition source 110.

Also, the deposition material may include a metal material for forming electrodes.

For example, to form a reflective layer of a pixel electrode, the deposition material may include argentum (Ag), magnesium (Mg), aluminum (Al), platinum (Pt), palladium (Pd), aurum (Au), nickel (Ni), neodymium (Nd), iridium (Ir), chromium (Cr), and a compound thereof. In addition, to form an electrode layer of a pixel electrode, the deposition material may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO).

In an embodiment, in order to form an opposite electrode, the deposition material may include a metal having a low work function, an alloy, an electrically conductive compound, or any combination thereof. In addition, the deposition material may include lithium (Li), argentum (Ag), magnesium (Mg), aluminum (Al), aluminum-lithium (Al—Li), calcium (Ca), magnesium-indium (Mg—In), magnesium-argentum (Mg—Ag), ytterbium (Yb), argentum-ytterbium (Ag—Yb), ITO, IZO, or any combination thereof.

In an embodiment, a plurality of barrier walls (not shown) may be installed in the deposition source 110 for dividing the inner space, so that the deposition material may not be locally concentrated and stored.

In an embodiment, the nozzle unit 120 may be disposed on the deposition source 110 to spray the deposition material onto the substrate SUB. The nozzle unit 120 may be disposed on at least one of both ends of the deposition source 110.

In an embodiment, the nozzle unit 120 may be disposed only on one side of the deposition source 110 in the first direction DR1 or on the other side of the deposition source 110 in the first direction DR1. Also, in another embodiment, the nozzle units 120 may be disposed on both ends of the deposition source 110. However, an embodiment in which the nozzle units 120 are disposed on both ends of the deposition source 110 is described below for convenience of description.

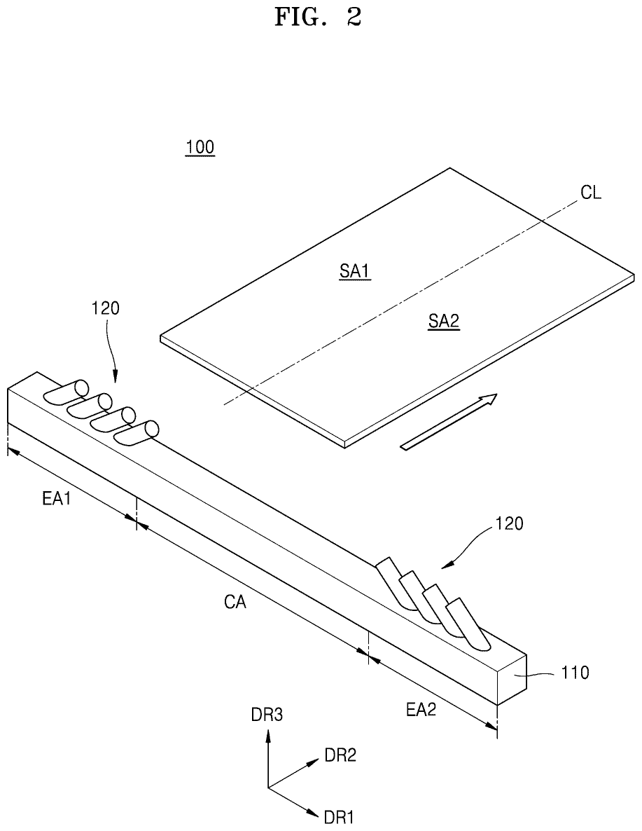

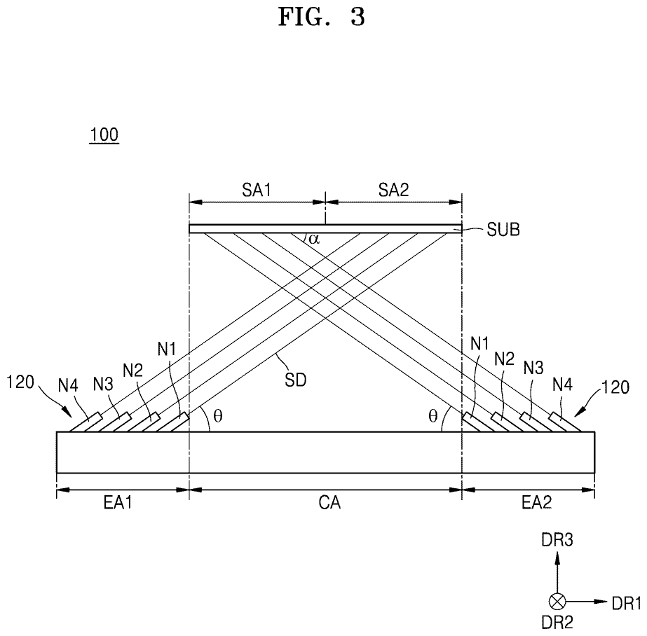

FIG. 2 is a diagram showing an example of the way of moving the deposition source 110 of FIG. 1, according to an embodiment, and FIG. 3 is a diagram showing an example of the deposition source 110 shown in FIG. 2, according to an embodiment.

For convenience of description, the substrate SUB, the deposition source 110, and the nozzle units 120 of FIG. 1 are shown in FIGS. 2 and 3, and the other components are omitted.

In an embodiment and referring to FIGS. 2 and 3, the deposition source 110 accommodates the deposition material in the inner space thereof, and the nozzle units 120 may be disposed on the deposition source 110. The deposition material stored in the deposition source 110 may be deposited on the substrate SUB through the nozzle units 120.

Hereinafter, a deposition direction SD is defined as a direction in which the deposition material is sprayed from the nozzle, and an inclination angle θ may be defined as an angle between the surface of the deposition source 110 and the deposition direction SD. Also, an incident angle α is an angle at which the deposition material is deposited on the substrate SUB, and may be defined as an angle between the surface of the substrate SUB and the deposition direction SD. As shown in FIG. 3, the substrate SUB may be arranged in parallel with the deposition source 110, and the inclination angle θ and the incident angle α correspond to each other and may be substantially equal to each other.

In an embodiment, an extending length of the deposition source 110 in the first direction DR1 may be greater than the width of the substrate SUB. Because the length of the deposition source 110 is set to be greater than the width of the substrate SUB, the deposition source 110 may have a region overlapping the substrate SUB and a region not overlapping the substrate SUB. The deposition source 110 may be divided into a central area CA, a first outer area EA1, and a second outer area EA2 in the first direction DR1.

In an embodiment, the central area CA may include the region overlapping the substrate SUB. The substrate SUB is arranged above the central area CA to face each other and may overlap each other.

For example, in one embodiment, the central area CA may be set to have a length that is substantially equal to the width of the substrate SUB.

In another example, in another embodiment, the central area CA may be set to have a length greater than the width of the substrate SUB, and the central area CA is arranged to partially face the substrate and both ends thereof may not face the substrate SUB. Here, the central area CA may be set so that the region overlapping the substrate SUB may be larger than the region not overlapping the substrate SUB.

In an embodiment, the first outer area EA1 and the second outer area EA2 may be disposed at both sides of the central area CA.

For example, in one embodiment, the first outer area EA1 and the second outer area EA2 are defined as regions not overlapping the substrate SUB, and the substrate SUB may not be arranged above the first outer area EA1 and the second outer area EA2.

In another example, in another embodiment, the first outer area EA1 and the second outer area EA2 may partially overlap the substrate SUB. Here, the first outer area EA1 and the second outer area EA2 may be set so that the regions not overlapping the substrate SUB may be larger than the overlapping region.

In an embodiment, the nozzle unit 120 may be disposed on at least one of the first outer area EA1 and the second outer area EA2. For example, the nozzle unit 120 may be disposed on the first outer area EA1 or the second outer area EA2. Also, the nozzle units 120 may be respectively disposed on the first outer area EA1 and the second outer area EA2.

Hereinafter, for convenience of description, the nozzle units 120 may be disposed on the first outer area EA1 and the second outer area EA2, and the nozzle units 120 may be arranged to face each other. The nozzle unit 120 disposed on the first outer area EA1 and the nozzle unit 120 disposed on the second outer area EA2 are substantially the same as each other in view of structures, except for the spray direction, and thus, overlapping descriptions may be omitted or briefly provided.

In an embodiment, the nozzle unit 120 may include a plurality of nozzles. The number of nozzles in the nozzle unit 120 is not limited to a specific number, and may be set variously according to the width of the substrate SUB, the deposition material, and the deposition region. However, for convenience of description, an example in which a first nozzle N1, a second nozzle N2, a third nozzle N3, and a fourth nozzle N4 are arranged in each nozzle unit 120 in an outward direction is described below.

In an embodiment, the nozzle unit 120 may include a plurality of nozzles spaced apart from each other with a preset interval therebetween. For example, the first nozzle N1, the second nozzle N2, the third nozzle N3, and the fourth nozzle N4 may be spaced apart from each other with a preset interval along the first direction DR1.

In an embodiment, the deposition direction SD of the deposition material sprayed from the nozzle unit 120 may have the inclination angle θ from the surface of the deposition source 110. The deposition direction SD of the first nozzle N1 to the fourth nozzle N4 may have a preset inclination angle θ from the surface of the deposition source 110.

In an embodiment, the nozzle unit 120 may have an inclination directed toward the central area CA. Each of the nozzles in the nozzle unit 120 may extend toward the substrate SUB with an inclination from the surface of the deposition source 110. At this time, each of the nozzles in the nozzle unit 120 extends parallel to the deposition direction SD, and thus, each nozzle may have the inclination angle θ with the surface of the deposition source 110. Thus, the deposition direction SD of each nozzle may have the inclination angle θ with the surface of the deposition source 110.

In another embodiment, although not shown in the drawings, the nozzle unit may be disposed on the deposition source 110 and the deposition direction SD in which the deposition material is sprayed may have the inclination angle θ toward the central area.

In an embodiment, the inclination angles θ of the first nozzles N1 to fourth nozzles N4 disposed on the first outer area EA1 in the deposition direction SD may be set to be substantially the same.

In an embodiment, the inclination angles θ of the first nozzles N1 to fourth nozzles N4 disposed on the second outer area EA2 in the deposition direction SD may be set to be substantially the same.

In an embodiment, the inclination angle θ of each nozzle arranged on the first outer area EA1 and the inclination angle θ of each nozzle arranged on the second outer area EA2 may be set to be the same as each other, except for the direction thereof.

In an embodiment, the inclination angle θ of the nozzle unit 120 may be set variously according to the deposition material deposited on the substrate SUB or the width of the substrate SUB.

In an embodiment, the nozzle unit 120 may spray the deposition material in the deposition direction SD between the first direction DR1 and the third direction DR3 due to the inclination angle θ. Here, because the substrate SUB is arranged to face the deposition source 110, the deposition material deposited on the substrate SUB may have the incident angle α that is substantially the same as the inclination angle θ.

In an embodiment, the substrate SUB may be divided into a first deposition area SA1 that is disposed adjacent to the first outer area EA1, and a second deposition area SA2 that is disposed adjacent to the second outer area EA2.

In an embodiment, the nozzle unit 120 deposits the deposition material on the area of the substrate SUB, which is disposed adjacent to the second outer area EA2, from the nozzle arranged on the first outer area EA1, and deposits the deposition material on the area of the substrate SUB, which is disposed adjacent to the first outer area EA1, from the nozzle arranged on the second outer area EA2.

In an embodiment, the nozzle unit 120 may set the inclination angle θ and the deposition direction SD so that the nozzles arranged on the first outer area EA1 may deposit the deposition material on the second deposition area SA2 of the substrate SUB. Also, the nozzle unit 120 may set the inclination angle θ and the deposition direction SD so that the nozzles arranged on the second outer area EA2 may deposit the deposition material onto the first deposition area SA1.

In an embodiment, the deposition material sprayed from the nozzle unit 120 may have a deposition directivity in the third direction DR3 and a deposition directivity in the first direction DR1 due to the inclination angle θ of each nozzle. The deposition directivity in the third direction DR3 affects the deposition of the deposition material on the substrate SUB in the height direction, and the deposition directivity in the first direction DR1 affects the deposition of the deposition material on the substrate SUB in the side direction.

In an embodiment, the nozzle unit 120 may have the inclination angle θ ranging from about 30° to about 75° on the surface of the deposition source 110 toward the substrate SUB. Each nozzle of the nozzle unit 120 may have the inclination angle θ ranging from about 30° to about 75° on the upper surface of the deposition source 110 with respect to the substrate SUB.

In an embodiment, because the nozzle unit 120 forms a low incident angle on the substrate SUB, a deposition layer may be formed in consideration of a structural shape or the structure on the substrate SUB formed in the previous process, even when there is no change in the pattern of the mask. Here, in various embodiments, the deposition layer may be continuous or discontinuous according to the structural shape or the structure.

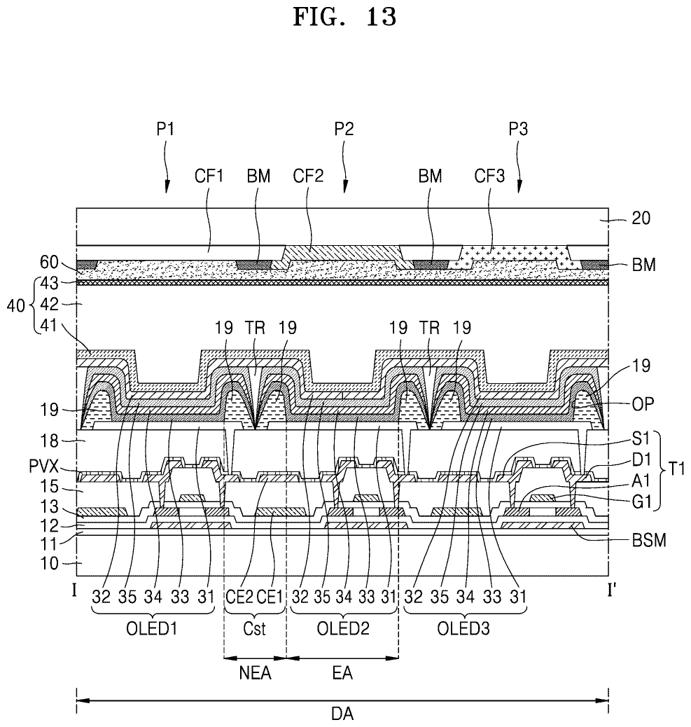

For example, in an embodiment, the deposition material may have a low incident angle on the substrate SUB depending on the inclination angle θ. As shown in FIG. 13, when a groove-shaped trench TR is arranged in a pixel-defining layer 19, the deposition material is deposited on a side wall of the trench TR, but does not completely fill in the groove. Thus, the deposition layer may be discontinued at the trench TR or may be deposited very thin, that is, a few tens of nm. Also, in the process of depositing another deposition material after the trench TR is filled to some extent, the deposition material may cover the entire upper portion of the trench TR. This will be described in more detail later.

In an embodiment, when the inclination angle θ of the nozzle unit 120 is less than about 30°, the directivity in the third direction DR3 may be weakened, and an efficiency of the deposition process may degrade. Also, because the number of nozzles has to be increased, the length of the deposition source 110 increases, and the size of the apparatus 100 for manufacturing the display device may also increase.

In an embodiment, when the inclination angle θ of the nozzle unit 120 exceeds about 75°, the directivity in the first direction DR1 is weakened and the deposition material has a large incident angle. Therefore, regardless of the shape or structure of the lower structure formed on the substrate SUB in the previous process, the deposition material that has passed through the transmission portion of the mask may form a deposition layer corresponding to the transmission portion of the substrate SUB.

For example, in an embodiment, even when the groove-shaped trench TR is provided in the pixel-defining layer 19 in FIG. 13, the deposition material fills the groove of the trench TR provided that the directivity of the deposition material in the third direction DR3, that is, the incident angle of the deposition material is increased, and thus, the deposition layer may be continuous on the trench TR. Here, when the incident angle of the deposition material is low, the deposition material is deposited on the side wall of the trench TR, but does not completely fill the groove, and thus, the deposition layer may be discontinued at the trench TR.

In an embodiment, the deposition source 110 may have a non-spray section in the central area (CA). The nozzle unit 120 may not be arranged on the central area CA of the deposition source 110.

In an embodiment, the deposition source 110 may be linearly moved by the transport portion LM and may be linearly moved due to the driving of the transport portion LM while the substrate SUB is arranged above the central area CA.

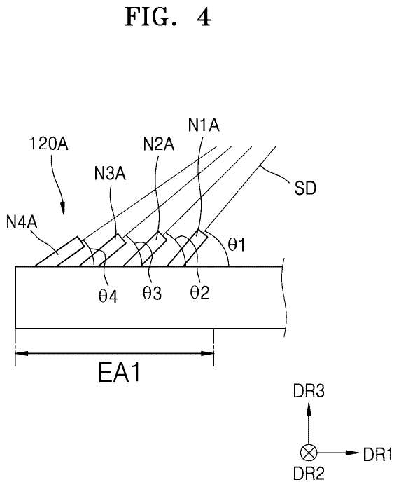

FIG. 4 is a diagram showing a modified example of a nozzle unit of FIG. 1, according to an embodiment.

In an embodiment and referring to FIG. 4, the display device manufacturing apparatus may include a deposition source and a nozzle unit 120A. When comparing with the above-described embodiment, the nozzle unit 120A is characterized in that the nozzles thereof have different inclination angles, and the difference is described in detail below.

In an embodiment, the nozzle unit 120A is disposed on each of the first outer area EA1 and the second outer area EA2, and may include a first nozzle N1A, a second nozzle N2A, a third nozzle N3A, and a fourth nozzle N4A.

In an embodiment, the nozzles of the nozzle unit 120A may have different inclination angles from one another. The first nozzle N1A has a first inclination angle θ1 directed in the first direction DR1, the second nozzle N2A has a second inclination angle θ2, the third nozzle N3A has a third inclination angle θ3, and the fourth nozzle N4A may have a fourth inclination angle θ4.

In an embodiment, at least one of the inclination angles θ1 to 04 may have an inclination angle this is different from the other inclination angles.

For example, in an embodiment, in the nozzle unit 120A, the inclination angles may be reduced from the first nozzle N1A to the fourth nozzle N4A. Also, although not shown in the drawings, in the nozzle unit 120A, the inclination angles may be increased from the first nozzle N1A to the fourth nozzle N4A.

In an embodiment, the nozzle unit 120A may have various deposition directions according to the deposition areas of the substrate SUB by setting the inclination angles of the respective nozzles differently.

In detail, in an embodiment, for an area that requires the deposition directivity from the deposition area in the third direction DR3, the nozzles may be set to have relatively greater inclination angles θ, and for an area that requires the deposition directivity from the deposition area in the first direction DR1, the nozzles may be set to have relatively less inclination angles θ.

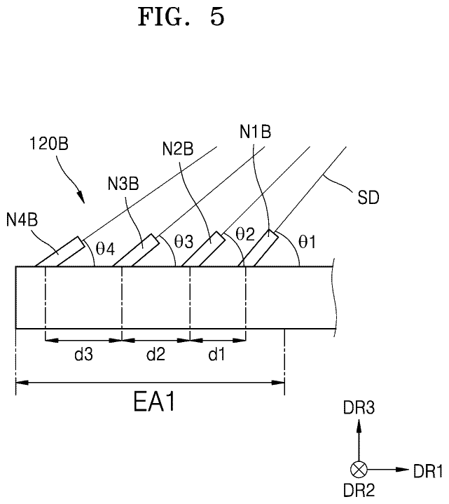

FIG. 5 is a diagram showing a modified example of a nozzle unit of FIG. 1, according to an embodiment.

In an embodiment and referring to FIG. 5, the display device manufacturing apparatus may include a deposition source and a nozzle unit 120B. When comparing with the above-described embodiment, the nozzle unit 120B is characterized in that the distances between the nozzles are different, and the difference is described in detail below.

In an embodiment, the nozzle unit 120B is disposed on each of the first outer area EA1 and the second outer area EA2, and may include a first nozzle N1B, a second nozzle N2B, a third nozzle N3B, and a fourth nozzle N4B.

In an embodiment, the first nozzle N1B and the second nozzle N2B is spaced apart from each other by a first distance d1, the second nozzle N2B and the third nozzle N3B are spaced apart from each other by a second distance d2, and the third nozzle N3B and the fourth nozzle N4B are spaced apart from each other by a third distance d3.

In an embodiment, at least one of the distances d1 to d3 may be different from other distances.

For example, in an embodiment, the separation distances in the nozzle unit 120B may be reduced from the first nozzle N1B to the fourth nozzle N4B. In addition, although not shown in the drawings, the separation distance in the nozzle unit 120B may be increased from the first nozzle N1B to the fourth nozzle N4B.

In an embodiment, the nozzle unit 120B may set various deposition degrees according to the deposition area of the substrate SUB by setting the separation distances between the nozzles differently. The distance between nozzles may be set in consideration of the shape of the lower structure formed on the substrate SUB in the previous process.

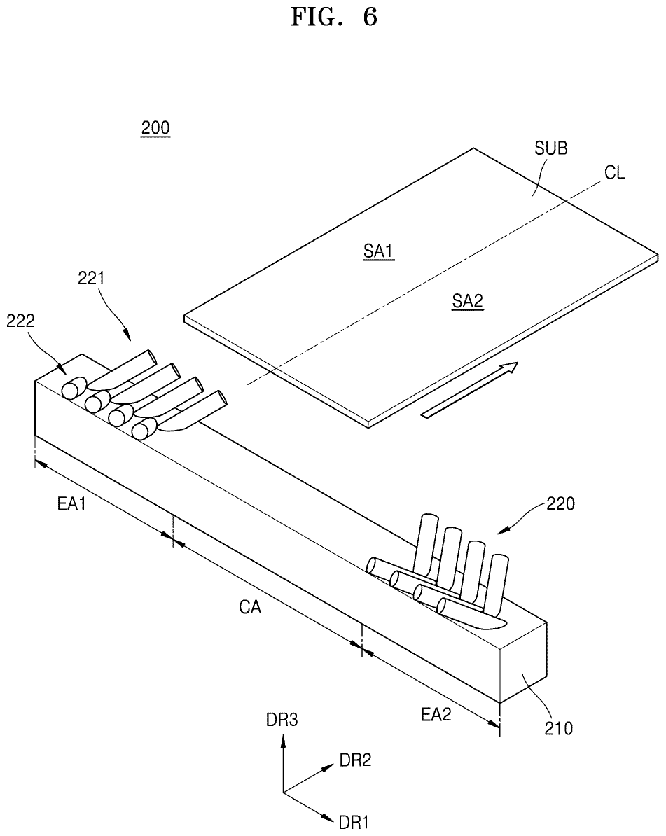

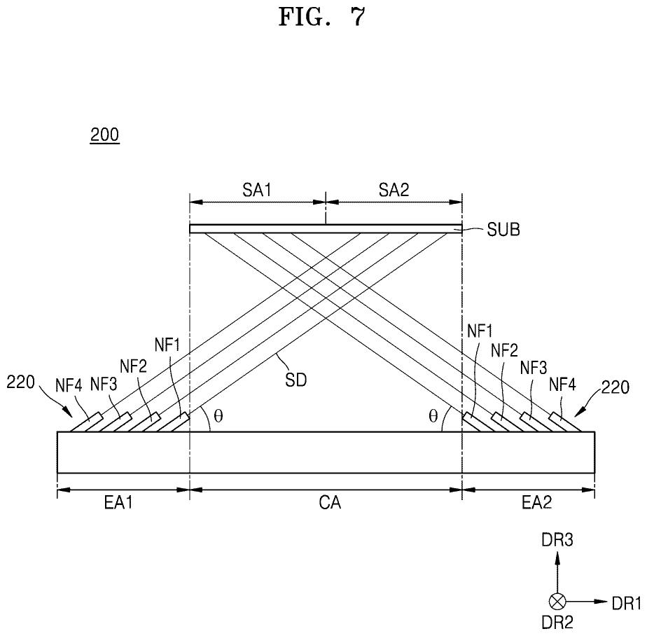

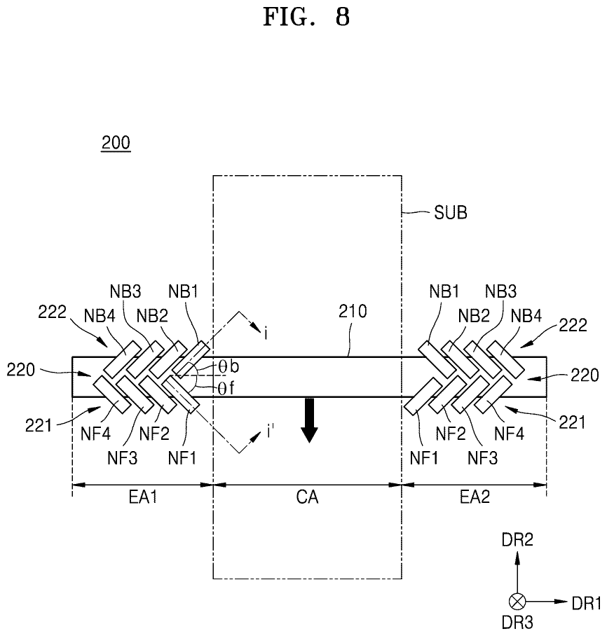

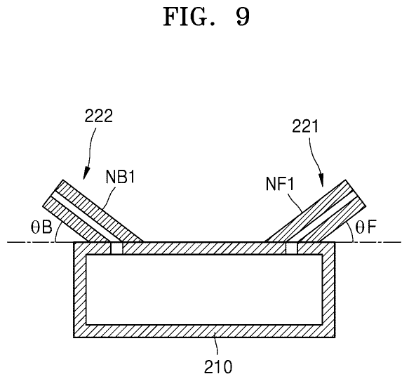

FIG. 6 is a diagram showing an example of how the deposition source according to another embodiment moves, and FIGS. 7 and 8 are diagrams showing examples of the deposition source of FIG. 6, according to an embodiment. FIG. 9 is a diagram showing a cross-section taken along line i-i′ of FIG. 8, according to an embodiment.

In an embodiment and referring to FIGS. 6 to 9, a display device manufacturing apparatus 200 may include a deposition source 210 and a nozzle unit 220. When comparing with the above-described embodiment, the display device manufacturing apparatus 200 differs from the above embodiment in view of the arrangement of the nozzle units 220, and hereinafter, the nozzle unit 220 is described in detail below.

In an embodiment, the nozzle unit 220 may spray the deposition material to the forward and backward directions of the second direction DR2. When the deposition source 210 moves in the second direction DR2, the deposition material may be sprayed with a low deposition direction toward the forward and backward directions.

In an embodiment, the nozzle unit 220 may include a first spray nozzle 221 having an inclination with respect to front portion of the direction in which the deposition source 210 moves, and a second spray nozzle 222 having an inclination to the rear portion of the direction in which the deposition source 210 moves.

In an embodiment, the first spray nozzle 221 and the second spray nozzle 222 may each have a plurality of nozzles, where the number of nozzles included in each of the first spray nozzle 221 and the second spray nozzle 222 are not limited to a specific number, and may be set variously according to the width of the substrate SUB, the deposition material, and the deposition area. However, for convenience of description, an example in which the first spray nozzle 221 includes a 1A nozzle NF1, a 2A nozzle NF2, a 3A nozzle NF3, and a 4A nozzle NF4, and the second spray nozzle 222 includes a 1B nozzle NB1, a 2B nozzle NB2, a 3B nozzle NB3, and a 4B nozzle NB4 is described below.

In an embodiment, in the nozzle unit 220, the first spray nozzle 221 and the second spray nozzle 222 may be alternately arranged with a preset interval along the lengthwise direction of the deposition source 210. The nozzle of the second spray nozzle 222 is arranged between adjacent nozzles of the first spray nozzle 221, and the nozzle unit 220 may be arranged to be concentrated in the first outer area EA1 and the second outer area EA2 so as to reduce the size of the apparatus 200 for manufacturing the display device.

In an embodiment, the first spray nozzle 221 and the second spray nozzle 222 may spray the deposition material to the front and rear portions in the direction in which the deposition source 210 moves, and the deposition area of the substrate may be expanded. In particular, in the nozzle unit 220, after spraying the deposition material from the first spray nozzle 221, the deposition material is also sprayed from the second spray nozzle 222, and thus, dual deposition operations are performed during one process, and the efficiency in the deposition process may be improved.

For example, in an embodiment, when an opposite electrode 32 is formed on a pixel-defining layer 19 in FIG. 13, the opposite electrode 32 may be continuously deposited on the pixel-defining layer 19 without being disconnected even when the deposition material sprayed from the first spray nozzle 221 and the second spray nozzle 222 is deposited with a low incident angle.

For example, in an embodiment, the first spray nozzle 221 may have a first inclination angle θf ranging from about 30° to about 75° in the lengthwise direction of the deposition source 210 toward the front portion. Also, the second spray nozzle 222 may have a second inclination angle θb ranging from about 30° to about 75° in the lengthwise direction of the deposition source 210 toward the rear portion. Therefore, the angle between the first spray nozzle 221 and the second spray nozzle 222 may range from about 60° to about 150°.

In an embodiment, the first inclination angle θf of the first spray nozzle 221 from the first direction DR1 directed toward the second direction DR2 and the second inclination angle θb of the second spray nozzle 222 from the first direction DR1 directed toward the second direction DR2 may have opposite directions to each other, and may have substantially the same degree. The display device manufacturing apparatus 200 may set the deposition area of the first spray nozzle 221 and the deposition area of the second spray nozzle 222 to be substantially equal to each other.

In an embodiment, the first inclination angle θf of the first spray nozzle 221 from the first direction DR1 directed toward the second direction DR2 and the second inclination angle θb of the second spray nozzle 222 from the first direction DR1 directed toward the second direction DR2 may have opposite directions to each other and may have different degrees. The display device manufacturing apparatus 200 sets the deposition area of the first spray nozzle 221 and the deposition area of the second spray nozzle 222 to be different from each other, and thus, the deposition process through the second spray nozzle 222 may supplement the deposition area formed by the first spray nozzle 221.

In an embodiment, the first spray nozzle 221 and the second spray nozzle 222 may have an inclination ranging from about 30° to about 75° on the surface of the deposition source 210 with respect to the substrate SUB. Each of the nozzles in the first spray nozzle 221 and the second spray nozzle 222 may have an inclination angle θF or θB ranging from about 30° to about 75° on the upper surface of the deposition source 210 with respect to the substrate SUB.

In an embodiment, because the first spray nozzle 221 and the second spray nozzle 222 have low incident angles with respect to the substrate SUB, a designed deposition layer may be formed in correspondence with the shape of the structure or the structure formed on the substrate SUB during the previous process, without replacing a mask.

In an embodiment, when the inclination angle θF or θB of the nozzle unit 220 is less than about 30°, the directivity in the third direction DR3 may be weakened, and an efficiency of the deposition process may degrade. Also, because the number of nozzles has to be increased, the length of the deposition source 210 increases, and the size of the apparatus 200 for manufacturing the display device may also increase.

In an embodiment, when the inclination angle θF or θB of the nozzle unit 220 exceeds about 75°, the directivity in the first direction DR1 is weakened and the deposition material has a large incident angle. Therefore, regardless of the shape or structure of the lower structure formed on the substrate SUB in the previous process, the deposition material that has passed through the transmission portion of the mask may form a deposition layer corresponding to the transmission portion of the substrate SUB.

For example, in an embodiment, even when the groove-shaped trench TR is provided in the pixel-defining layer 19 in FIG. 13, the deposition material has a large incident angle, and thus, the groove of the trench TR is filled, and thus, the deposition layer may be continuous on the trench TR.

In an embodiment and referring to FIG. 9, because the first spray nozzle 221 has the inclination from the first direction DR1 directed toward the third direction DR3 and the inclination from the first direction DR1 directed toward the second direction DR2, the first nozzle unit 220 may have a front inclination angle θF on the deposition source 210. In addition, because the second spray nozzle 222 has the inclination from the first direction DR1 toward the third direction DR3 and the inclination from the first direction DR1 toward the second direction DR2, the first nozzle unit 220 may have a rear inclination angle θB on the deposition source 210.

In an embodiment, due to the front inclination angle θF of the first spray nozzle 221 and the rear inclination angle θB of the second spray nozzle 222, the deposition material has a low incident angle with respect to the substrate SUB and may be deposited on the substrate SUB in a diagonal direction of a plane formed by the first direction DR1 and the second direction DR2. Here, the diagonal direction in which the first spray nozzle 221 performs spraying and the diagonal direction in which the second spray nozzle 222 performs spraying may be directed opposite to each other.

In an embodiment, the nozzle unit 220 deposits the deposition material on the area of the substrate SUB, which is disposed adjacent to the second outer area EA2, from the nozzle arranged on the first outer area (EA1), and deposits the deposition material on the area of the substrate SUB, which is disposed adjacent to the first outer area EA1, from the nozzle arranged on the second outer area EA2.

In an embodiment, the first spray nozzle 221 and the second spray nozzle 222 disposed on the first outer area EA1 may deposit the deposition material on the second deposition area SA2 of the substrate SUB. The first spray nozzle 221 and the second spray nozzle 222 disposed in the second outer area EA2 may deposit the deposition material on the first deposition area SA1 of the substrate SUB.

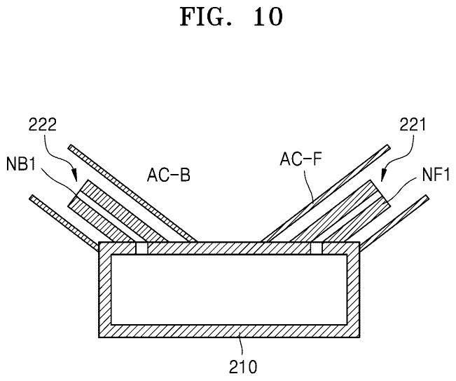

FIG. 10 is a diagram showing a modified example of FIG. 9, according to an embodiment.

In an embodiment and referring to FIG. 10, the nozzle unit may have a guide nozzle for restricting a spray angle of the deposition material, where the guide nozzle is disposed outside each nozzle to restrict the spray angle and improve straightness of the deposition material.

In an embodiment, the first spray nozzle 221 may have a first guide nozzle AC-F, and the second spray nozzle 222 may have a second guide nozzle AC-B, where the first guide nozzle AC-F and the second guide nozzle AC-B may be arranged for each nozzle. Also, the first guide nozzle AC-F and the second guide nozzle AC-B may be arranged for each of nozzle groups, the nozzle groups each include a plurality of nozzles.

In an embodiment, the first guide nozzle AC-F may be disposed on the outside of the first spray nozzle 221 and may strengthen the straightness of the deposition material. When the first guide nozzle AC-F is disposed outside the 1A nozzle NF1, the deposition material sprayed from the 1A nozzle NF1 may collide with the first guide nozzle AC-F and the straightness of the deposition material is improved.

In an embodiment, the second guide nozzle AC-B may be disposed on the outside of the second nozzle unit 220 and may strengthen the straightness of the deposition material. When the second guide nozzle AC-B is disposed outside the 2A nozzle NF2, the deposition material sprayed from the 2A nozzle NF2 may collide with the second guide nozzle AC-B and the straightness of the deposition material is improved.

In an embodiment, the first guide nozzle AC-F and the second guide nozzle AC-B prevent shadows from being generated on the areas where the deposition needs to be performed, and thus, the deposition material may be deposited at a required position on the substrate SUB to a required thickness. Therefore, a defective rate of a display panel in the display device may be decreased, and in particular, excellent deposition quality may be implemented in the display panel that is required to have ultra-high resolution.

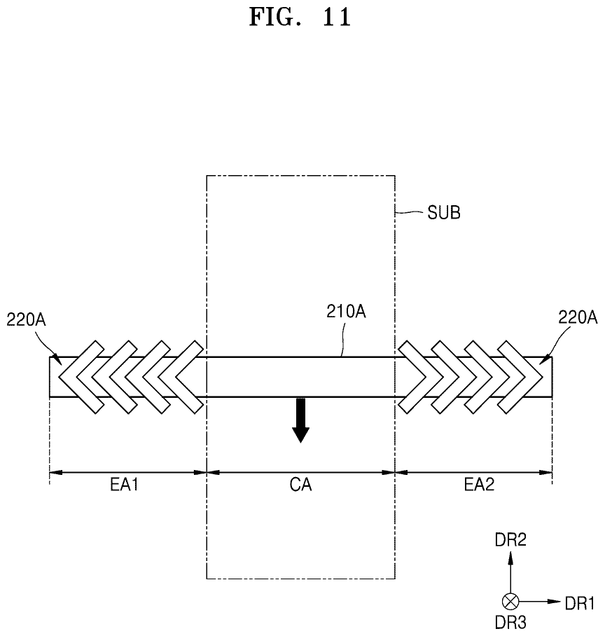

FIG. 11 is a diagram showing a deposition source of FIG. 6, according to another embodiment.

In an embodiment and referring to FIG. 11, nozzle units 220A may be disposed on the first outer area EA1 and the second outer area EA2 of a deposition source 210A. When comparing with the above-described embodiment, the nozzle unit 220A differs from the above embodiment in the shape of the nozzles, and hereinafter, each of nozzles in the nozzle unit 220A is described below.

In an embodiment, the nozzle unit 220A may include first spray nozzles having an inclination with respect to the front portion of the direction in which the deposition source 210A moves and second spray nozzles having an inclination directed toward the rear portion of the direction in which the deposition source 210A moves.

In an embodiment, the first and second spray nozzles of the nozzle unit 220A may be arranged in parallel to each other in the width direction of the deposition source 210A. The deposition source 210A may have a preset width in the second direction DR2, and the first and second spray nozzles may be arranged in parallel to each other in the width direction.

In an embodiment, the first spray nozzle and the second spray nozzle may be integrally formed with each other and may extend as one body on the deposition source 210A. The first spray nozzle may have an inclination in a diagonal direction of the front portion of the movement direction and the second spray nozzle may have an inclination in a diagonal direction of the rear portion of the movement direction.

A display device manufacturing method, according to another embodiment may include preparing a deposition source having a central area and nozzle units arranged on a first outer area and a second outer area that are arranged on both sides of the central area, arranging a substrate above the central area, and depositing a deposition material on the substrate while moving the deposition source.

In an embodiment, in the display device manufacturing method, the nozzle unit 120 or 220 may have an inclination directed toward the central area CA. Also, the deposition source 110 or 210 may have a non-spray section in the central area CA.

In an embodiment, according to the display device manufacturing method, the nozzle unit 120 or 220 disposed on the first outer area EA1 may deposit the deposition material on an area of the substrate SUB, which is disposed adjacent to the second outer area EA2, and the nozzle unit 120 or 220 disposed on the second outer area EA2 may deposit the deposition material on an area of the substrate SUB, which is disposed adjacent to the first outer area EA1.

In an embodiment, according to the display device manufacturing method, when the deposition material is deposited on the substrate, the first spray nozzle 221 having the inclination directed toward the front portion of the direction in which the deposition source 210 moves may deposit the deposition material on the front portion of the deposition material with a low incident angle, and the second spray nozzle 222 having the inclination directed toward the back of the direction in which the deposition source 210 moves may deposit the deposition material on the back of the deposition source 210 with a low incident angle.

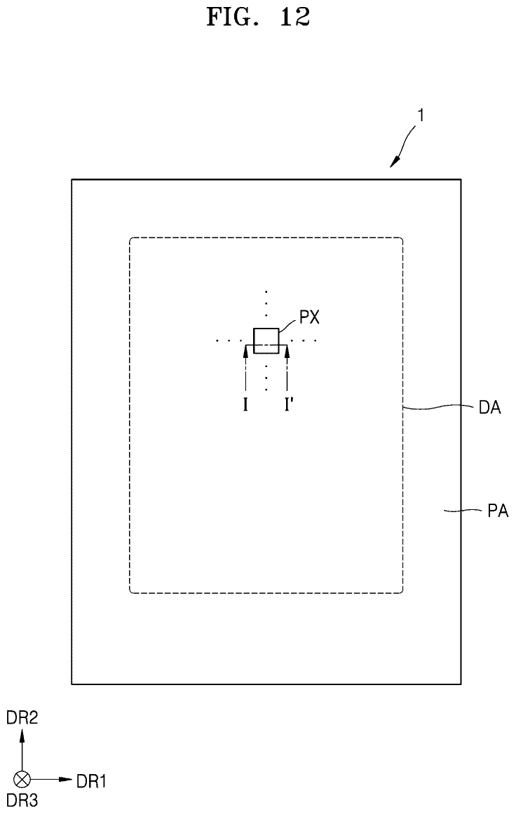

FIG. 12 is a plan view of a display device 1 manufactured by the display device manufacturing apparatus, according to an embodiment.

Referring to FIG. 12, the display device 1 manufactured according to an embodiment may include a display area DA and a peripheral area PA located outside the display area DA, where the display device 1 may provide images via arrays of a plurality of pixels PX that are two-dimensionally arranged in the display area DA.

In an embodiment, the peripheral area PA does not provide images and may partially or entirely surround the display area DA. Drivers, etc. for providing electrical signals or electric power to a pixel circuit corresponding to each of the plurality of pixels PX may be in the peripheral area PA. The peripheral area PA may include a pad that is a region to which an electronic device, a printed circuit board, etc. may be electrically connected.

Hereinafter, an embodiment is described where the display device 1 includes an organic light-emitting diode (OLED) as a light-emitting element, but the display device 1 of the invention is not limited thereto. In another embodiment, the display device 1 may be a light-emitting display device including an inorganic light-emitting diode, that is, an inorganic light-emitting display device. The inorganic light-emitting diode may include a PN diode including inorganic material semiconductor-based materials. When a voltage is applied to the PN junction diode in a forward direction, holes and electrons are injected, and energy generated by recombination of the holes and electrons is converted into light energy to emit light having a certain color. The inorganic light-emitting diode may have a width of a few to hundreds of micrometers, and in some embodiments, the inorganic light-emitting diode may be referred to as a micro-LED. In another embodiment, the display device 1 may include a quantum dot light-emitting display.

In addition, in an embodiment, the display device 1 may be used as a display screen in portable electronic devices such as a mobile phone, a smartphone, a tablet personal computer (PC), a mobile communication terminal, an electronic note, an electronic book, a portable multimedia player (PMP), a navigation device, an ultra-mobile PC (UMPC), and various products such as a television, a laptop computer, a monitor, a billboard, Internet of things (IoT), etc. Also, the display device 1 may be used in wearable devices such as a smartwatch, a watch phone, a glasses-type display, and a head-mounted display (HMD). Also, the display device 1 may be used in a dashboard of a vehicle, a center information display in a center fascia or dashboard of a vehicle, a rear-view mirror display that replaces a side-view mirror of a vehicle, a display screen in a rear side of a front seat as an entertainment for the back seat in a vehicle.

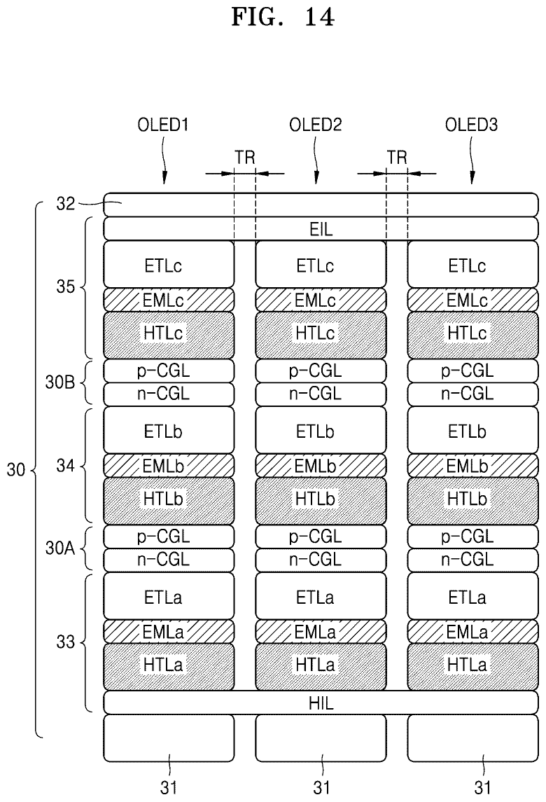

FIG. 13 is a cross-sectional view taken along line I-I′ of FIG. 12, according to an embodiment, and FIG. 14 is a diagram conceptionally showing part of FIG. 13, according to an embodiment.

Referring to FIGS. 13 and 14, at least one thin film transistor T1 and a display element connected to the thin film transistor T1 may be disposed on the display area DA of the display device 1 according to an embodiment. In the display area DA, the driving thin film transistor T1 and a storage capacitor Cst in the pixel circuit are shown.

In an embodiment, the display area DA of the display device 1 includes a plurality of subpixels P1, P2, and P3, where each of the sub-pixels P1, P2, and P3 includes an emission area EA. The emission area EA may be a region in which light is generated and emitted to the outside. The non-emission area NEA is located between the emission areas EA, and the emission areas EA of the sub-pixels P1, P2, and P3 may be partitioned by the non-emission area NEA.

In an embodiment, a first organic light-emitting diode OLED1, a second organic light-emitting diode OLED2, and a third organic light-emitting diode OLED3 included in the first sub-pixel P1, the second sub-pixel P2, and the third sub-pixel P3 may emit light of the same color.

In another embodiment, at least one of the first organic light-emitting diode OLED1, the second organic light-emitting diode OLED2, and the third organic light-emitting diode OLED3 included in the first sub-pixel P1, the second sub-pixel P2, and the third sub-pixel P3 may emit light of a different color from the other.

For convenience of description, elements in the display area DA of FIG. 12 will be described according to a stacking order.

In an embodiment, the substrate 10 may include a glass material, a ceramic material, a metal material, or a flexible or bendable material. When the substrate 10 is flexible or bendable, the substrate 10 may include a polymer resin such as a polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate (CAP). The substrate 10 may have a single-layered or a multi-layered structure of the above material, and the multi-layered structure may further include an inorganic layer. In some embodiments, the substrate 10 may have a structure including an organic material/inorganic material/organic material.

In an embodiment, a barrier layer (not shown) may be further provided between the substrate 10 and a buffer layer 11, where the barrier layer may prevent or reduce infiltration of impurities from the substrate 10, etc. into a semiconductor layer A1. The barrier layer may include an inorganic material such as an oxide material or a nitride material, an organic material, or an inorganic-organic composite material, and may have a single-layered or multi-layered structure including the inorganic material and the organic material.

In an embodiment, a bias electrode BSM may be disposed on the first buffer layer 11 to correspond to the driving thin film transistor T1. A voltage may be applied to the bias electrode BSM. For example, in an embodiment, the bias electrode BSM may be connected to a source electrode of a sensing thin film transistor, and a voltage of the source electrode may be applied to the bias electrode BSM. Also, the bias electrode BSM may prevent external light from reaching the semiconductor layer A1. Accordingly, characteristics of the thin film transistor T1 may be stabilized. The bias electrode BSM may be omitted in another embodiment.

In an embodiment, the semiconductor layer A1 may be disposed on a second buffer layer 12, where the semiconductor layer A1 may include amorphous silicon or polysilicon. In another embodiment, the semiconductor layer A1 may include an oxide of at least one selected from the group consisting of indium (In), gallium (Ga), stannum (Sn), zirconium (Zr), vanadium (V), hafnium (Hf), cadmium (Cd), germanium (Ge), chrome (Cr), titanium (Ti), aluminum (Al), cesium (Cs), cerium (Ce), and zinc (Zn). In some embodiments, the semiconductor layer A1 may include Zn oxide-based material, e.g., Zn oxide, In—Zn oxide, Ga—In—Zn oxide, etc. In another embodiment, the semiconductor layer A1 may include In—Ga—Zn—O (IGZO), In—Sn—Zn—O (ITZO), or In—Ga—Sn—Zn—O (IGTZO) semiconductor including ZnO with metal such as In, Ga, and Zn. The semiconductor layer A1 may include a channel region and a source region and a drain region at opposite sides of the channel region. The semiconductor layer A1 may have a single-layered or multi-layered structure.

In an embodiment, a gate electrode G1 is disposed over the semiconductor layer A1 with a gate insulating layer 13 disposed therebetween, and the gate electrode G1 at least partially overlaps the semiconductor layer A1. The gate electrode G1 may include molybdenum (Mo), aluminum (Al), copper (Cu), titanium (Ti), etc., and may have a single-layered or multi-layered structure. As an example, the gate electrode G1 may include a single layer including Mo. A first electrode CE1 of the storage capacitor Cst is at the same layer as the gate electrode G1. The first electrode CE1 may include the same material as that of the gate electrode G1.

In an embodiment, an interlayer insulating layer 15 may cover the gate electrode G1 and the first electrode CE1 of the storage capacitor Cst, where the interlayer insulating layer 15 may include an insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), and zinc oxide (ZnO₂).

In an embodiment, a second electrode CE2 of the storage capacitor Cst, a source electrode S1, a drain electrode D1, and a data line may be disposed on the interlayer insulating layer 15.

In an embodiment, the second electrode CE2 of the storage capacitor Cst, the source electrode S1, the drain electrode D1, and the data line DL may include a conductive material including Mo, Al, Cu, Ti, etc. and may have a single-layered or multi-layered structure including the above materials. In an embodiment, the second electrode CE2, the source electrode S1, the drain electrode D1, and the data line DL may each have a multi-layered structure including Ti/Al/Ti. The source electrode S1 and the drain electrode D1 may be connected to the source region or the drain region of the semiconductor layer A1 via contact holes.

In an embodiment, the second electrode CE2 of the storage capacitor Cst overlaps the first electrode CE1 with the interlayer insulating layer 15 disposed therebetween and forms a capacitance. In this case, the interlayer insulating layer 15 may function as a dielectric layer of the storage capacitor Cst.

In an embodiment, the second electrode CE2 of the storage capacitor Cst, the source electrode S1, the drain electrode D1, and the data line DL may be covered by an inorganic protective layer PVX.

In an embodiment, the inorganic protective layer PVX may have a single-layered or multi-layered structure including silicon nitride (SiNx) and silicon oxide (SiOx). The inorganic protective layer PVX may be introduced to cover and protect some wirings on the interlayer insulating layer 15. In a partial area of the substrate 10 (e.g., a part of the peripheral area), wirings (not shown) manufactured with the data line DL through the same manufacturing process may be exposed. Exposed parts of the wirings may be damaged due to an etchant that is used in patterning of a pixel electrode 31 that will be described later. However, because the inorganic protective layer PVX at least partially covers the data line DL and the wirings manufactured with the data line DL, damage to the wirings during the patterning of the pixel electrode 31 may be prevented.

In an embodiment, a planarization layer 18 is on the inorganic protective layer PVX and the organic light-emitting diodes (OLED1, OLED2, and OLED3) may be on the planarization layer 18.

In an embodiment, the planarization layer 18 may include a single-layered or multi-layered structure including an organic material, and may provide a planarized upper surface. The planarization layer 18 may include a universal polymer (benzocyclobutene (BCB), polyimide (PI), hexamethyldisiloxane (HMDSO), polymethylmethacrylate (PMM), or polystyrene (PS)), polymer derivatives having phenol groups, acryl-based polymer, imide-based polymer, aryl ether-based polymer, amide-based polymer, fluoride-based polymer, p-xylene-based polymer, vinyl alcohol-based polymer, and mixtures thereof.

In an embodiment, in the display area DA of the substrate 10, the organic light-emitting diodes OLED1, OLED2, and OLED3 are disposed on the planarization layer 18. The first organic light-emitting diode OLED1 may be arranged in the area of the first sub-pixel P1, the second organic light-emitting diode OLED2 may be arranged in the area of the second sub-pixel P2, and the third organic light-emitting diode OLED3 may be arranged in the area of the third sub-pixel P3. The organic light-emitting diodes OLED1, OLED2, and OLED3 may each include the pixel electrode 31, an intermediate layer including an emission layer, and the opposite electrode 32.

In an embodiment, the pixel electrode 31 may be patterned for each of the organic light-emitting diodes OLED1, OLED2, and OLED3 on the planarization layer 18. The pixel electrode 31 may be electrically connected to the pixel circuit.

In an embodiment, he pixel electrode 31 may be a (semi-) transmissive electrode or a reflective electrode. In some embodiments, the pixel electrode 31 may include a reflective layer including Ag, Mg, Al, Pt, Pd, Au, Ni, Nd, Ir, Cr, and a compound thereof, and a transparent or semi-transparent electrode layer on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide, and aluminum zinc oxide (AZO). In some embodiments, the pixel electrode 31 may include ITO/Ag/ITO.

In an embodiment, the pixel-defining layer 19 may be on the planarization layer 18, and the pixel-defining layer 19 includes an opening corresponding to each of the sub-pixels in the display area DA, that is, an opening OP exposing at least a central portion of the pixel electrode 31 to define a light-emitting region of the sub-pixel. Also, the pixel-defining layer 19 increases a distance between an edge of the pixel electrode 31 and the opposite electrode 32 on the pixel electrode 31 to prevent generation of arc at the edge of the pixel electrode 31.

In an embodiment, the pixel-defining layer 19 may include one or more organic insulating materials selected from the group consisting of polyimide, polyamide, acryl resin, BCB, and phenol resin, and may be manufactured by a spin coating method, etc.

In an embodiment, the pixel-defining layer 19 may have the trench TR. The trench TR may have a concave groove shape in the thickness direction of the pixel-defining layer 19. The trench TR cuts off the intermediate layers of the organic light-emitting diodes OLED1 to OLED3, and the opposite electrode 32 may cover the upper portion of the trench TR.

In an embodiment, because the trench TR cuts off the intermediate layer in each sub-pixel, light emission from the sub-pixels other than the target sub-pixel due to the leakage of current to the intermediate layers or charge generating layers of adjacent organic light-emitting diodes may be prevented.

In an embodiment, the organic-light emitting diodes OLED1 to OLED3 may include a plurality of intermediate layers. Each of the intermediate layers may further include a hole injection layer (HIL), an electron transport layer (ETL), and an electron injection layer (EIL) on upper and lower portions of the emission material layer (EML).

In an embodiment, each organic light-emitting diode may include a first intermediate layer 33, a second intermediate layer 34, and a third intermediate layer 35.

In an embodiment, the first intermediate layer 33 may include a first emission layer EMLa, a first hole transport layer HTLa, and a first electron transport layer ETLa. The second intermediate layer 34 may include a second emission layer EMLb, a second hole transport layer HTLb, and a second electron transport layer ETLb. The third intermediate layer 35 may include a third emission layer EMLc, a third hole transport layer HTLc, and a third electron transport layer ETLc.

In an embodiment, the intermediate layers 35 of the first organic light-emitting diode OLED1 may be isolated from the intermediate layers 35 of the second organic light-emitting diode OLED2 and the third organic light-emitting diode OLED3 due to the trench TR.

In an embodiment, the first emission layer EMLa, the second emission layer EMLb, and the third emission layer EMLc may emit light of different colors. In some embodiments, the first emission layer EMLa may include an organic material emitting green light, the second emission layer EMLb may include an organic material emitting blue light, and the third emission layer EMLc may include an organic material emitting red light.

In an embodiment, a first charge generation layer 30A may supply charges to the first intermediate layer 33 and the second intermediate layer 34. The first charge generation layer 30A may include an n-type charge generation layer n-CGL for supplying electrons to the first intermediate layer 33, and a p-type charge generation layer p-CGL for supplying holes to the second intermediate layer 34. The n-type charge generation layer n-CGL may include a metal material as a dopant.

In an embodiment, the second charge generation layer 30B may supply charges to the second intermediate layer 34 and the third intermediate layer 35. The second charge generation layer 30B may include an n-type charge generation layer n-CGL for supplying electrons to the second intermediate layer 34, and a p-type charge generation layer p-CGL for supplying holes to the third intermediate layer 35. The n-type charge generation layer n-CGL may include a metal material as a dopant.

In an embodiment, the opposite electrode 32 may be a cathode, which is an electron injection electrode, and in this case, a material for the opposite electrode 32 may include a metal, alloy, electrically conductive compound, or any combination thereof having a low work function. The opposite electrode 32 may be a transmissive electrode, a (semi-) transmissive electrode, or a reflective electrode.

In an embodiment, the opposite electrode 32 may include lithium (Li), argentum (Ag), magnesium (Mg), aluminum (Al), aluminum-lithium (Al—Li), calcium (Ca), magnesium-indium (Mg—In), magnesium-argentum (Mg—Ag), ytterbium (Yb), argentum-ytterbium (Ag—Yb), ITO, IZO, or any combination thereof. The opposite electrode 32 may have a single-layered structure including a single layer or a multi-layered structure including a plurality of layers.

In an embodiment, the opposite electrode 32 is arranged throughout the display area DA and the peripheral area PA, and on the intermediate layer and the pixel-defining layer 19. The opposite electrode 32 may be provided integrally with respect to the plurality of organic light-emitting diodes OLED1, OLED2, and OLED3 to correspond to the plurality of pixel electrodes 31.

In an apparatus and method for manufacturing the display device according to an embodiment, the incident angle of the deposition material that is incident on the substrate is set to be low, and the intermediate layers are disconnected by the trench TR of the pixel-defining layer 19. Thus, the leakage of current to the organic light-emitting diodes of the other sub-pixels may be reduced.

In an embodiment, the display device 1 has at least one intermediate layer in each of the organic light-emitting diodes, and the charge generation layer may be disposed between the intermediate layers. Due to the stack structure, even when the current is supplied to the first organic light-emitting diode OLED in order to emit light only from the first organic light-emitting diode OLED1, another sub-pixel may emit light and the performance of the display device 1 may degrade provided that the current is supplied to the adjacent second organic light-emitting diode OLED 2 or the third organic light-emitting diode OLED3 via the charge generation layer.

In an embodiment, the trench TR formed in the pixel-defining layer 19 may cut off the connection of the intermediate layers, and in particularly, the connection of the charge generation layers, and thus, the trench TR may control the display device to be displayed only on the target sub-pixel.

In detail, in the apparatus 100 and method for manufacturing the display device, according to an embodiment, the incident angle of the deposition material on the substrate 10 may be set to be low so that the intermediate layer or the charge generation layer may be deposited on the side wall of the trench TR. That is, because the nozzle units 120 are disposed on both ends of the deposition source 110 to have the inclination angles, the deposition material may be incident on the substrate with the low incident angle. When the deposition material is deposited with the low incident angle, the intermediate layer or the charge generation layer is formed on the side wall of the trench TR, and is disconnected at the trench TR.

According to an embodiment of the display device manufacturing apparatus and method, the deposition material is sprayed to the forward and backward of the deposition source, and thus, the opposite electrode 32, that is, the common layer, may be continuously formed. That is, the opposite electrode 32 may be formed above the pixel-defining layer 19 so as to cover the trench TR.

In detail, in an embodiment of the apparatus 100 for manufacturing the display device, after the intermediate layers and the charge generation layer are formed on the side wall of the trench TR, the nozzle unit 120 sprays different deposition material to form the opposite electrode 32 covering the trench TR. Here, the intermediate layers and the charge generation layer are disconnected due to the trench TR, but the opposite electrode 32 is continuously formed without being disconnected, thereby improving the performance of the display device 1. In particular, because the first spray nozzle 221 and the second spray nozzle 222 in the nozzle unit 120 spray the deposition materials to the forward and backward of the direction in which the deposition source 110 moves, the opposite electrode 32 may be formed continuously throughout the upper portion of the trench TR and the upper portion of the adjacent organic light-emitting diodes.

In an embodiment, because the organic light-emitting diodes OLED1, OLED2, and OLED3 may be easily damaged due to moisture or oxygen from the outside, the organic light-emitting diodes OLED1, OLED2, and OLED3 may be covered and protected by a thin film encapsulation layer 40. The thin film encapsulation layer 40 covers the display area DA and may extend to the outside of the display area DA. The thin film encapsulation layer 40 includes at least one organic encapsulation layer and at least one inorganic encapsulation layer. For example, the thin film encapsulation layer 40 may include a first inorganic encapsulation layer 41, an organic encapsulation layer 42, and a second inorganic encapsulation layer 43.

In an embodiment, the first inorganic encapsulation layer 41 covers the opposite electrode 32 and may include silicon oxide, silicon nitride, and/or silicon oxynitride. Although not shown in the drawings, other layers such as a capping layer may be provided between the first inorganic encapsulation layer 41 and the opposite electrode 32, as necessary. Because the first inorganic encapsulation layer 41 is formed along a structure thereunder, the first inorganic encapsulation layer 41 has an uneven upper surface. The organic encapsulation layer 42 covers the first inorganic encapsulation layer 41, and unlike the first inorganic encapsulation layer 41, the organic encapsulation layer 42 may have a flat upper surface.

In detail, in an embodiment, the organic encapsulation layer 42 may planarize the upper surface of a portion corresponding to the display area DA. The organic encapsulation layer 42 may include one or more materials selected from the group consisting of polyethylene terephthalate, polyethylene naphthalate, polycarbonate, polyimide, polyethylene sulfonate, polyoxymethylene, polyarylate, and hexamethyl disiloxane. The second inorganic encapsulation layer 43 may cover the organic encapsulation layer 42, and may include SiOx, SiNx, and/or SiON.

In an embodiment, even when cracks occur in the thin film encapsulation layer 40, the cracks may be disconnected between the first inorganic encapsulation layer 41 and the organic encapsulation layer 42 or between the organic encapsulation layer 42 and the second inorganic encapsulation layer 43 owing to the multi-layered structure in the thin film encapsulation layer 40. As such, generation of an infiltration path through which the external moisture or oxygen passes to the display area DA may be prevented or reduced.

In an embodiment, a filler 60 may be disposed on the thin film encapsulation layer 40. The filler 60 may buffer external pressure, etc. The filler 60 may include an organic material such as methyl silicone, phenyl silicone, polyimide, etc. However, one or more embodiments are not limited thereto, and the filler 60 may include an organic sealant such as a urethane-based resin, or an epoxy-based resin, an acryl-based resin, or an inorganic sealant such as silicone.

In an embodiment, a first color filter CF1, a second color filter CF2, and a third color filter CF3 and a light-blocking pattern BM may be provided on an upper substrate 20 facing the substrate 10.

In an embodiment, the color filters CF1, CF2, and CF3 may be adopted in order to implement full-color images, improve color purity, and improve outdoors visibility. The first color filter CF1 may transmit the light emitted from the first organic light-emitting diode OLED1, the second color filter CF2 may transmit the light emitted from the second organic light-emitting diode OLED2, and the third color filter CF3 may transmit the light emitted from the third organic light-emitting diode OLED3. In some embodiments, the first color filter CF1 may be red, the second color filter CF2 may be green, and the third color filter CF3 may be blue.

In an embodiment, the light-blocking pattern BM may be arranged among the color filters CF1, CF2, and CF3 to correspond to the non-emission area NEA. The light-blocking pattern BM may include a black matrix and may improve color sharpness and contrast. The light-blocking pattern BM may include at least one selected from black pigment, black dye, and black particles. In some embodiments, the light-blocking pattern BM may include a material such as Cr or CrOx, Cr/CrOx, Cr/CrOx/CrNy, a resin (carbon pigment, RGB mixture pigment), graphite, a non-Cr based material, etc.

In an embodiment, the color filters, from among the color filters CF1, CF2, and CF3, arranged to be disposed adjacent to each other may be arranged to overlap each other in the non-emission area NEA. Because the color filters of different colors are provided to overlap each other, the light blocking rate may be improved. The color filters CF1, CF2, and CF3 and the light-blocking pattern BM may be omitted in some cases.

The above embodiments may be implemented as separate embodiments or they may be combined with each other.

According to an embodiment, the deposition layer is formed according to the shape of the lower structure of the substrate, and thus, the processing efficiency may be improved and the display device with high reliability may be manufactured.

While the invention has been particularly shown and described with reference to exemplary embodiments thereof, it will be understood by those of ordinary skill in the art that various changes in form and details may be made therein without departing from the spirit and scope as defined by the following claims.

According to the embodiments of the invention, the display device manufacturing apparatus and method, in which the deposition material may be effective sprayed in correspondence with the lower structure on the substrate, may be provided. Also, the leakage of current to adjacent sub-pixels may be prevented, and thus, the display device with high reliability may be manufactured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the invention.

What is claimed is:

1. A display device manufacturing apparatus comprising:
a deposition source, wherein the deposition source accommodates a deposition material and includes a central area facing a substrate, and a first outer area and a second outer area disposed on both sides of the central area; and
a nozzle unit disposed on at least one of the first outer area and the second outer area, and having an inclination toward the central area.

2. The display device manufacturing apparatus of claim 1, wherein
the nozzle unit comprises:
a first spray nozzle having an inclination toward a front portion of a direction in which the deposition source moves; and
a second spray nozzle having an inclination toward a rear portion of the direction in which the deposition source moves.

3. The display device manufacturing apparatus of claim 2, wherein,
in the nozzle unit,
the first spray nozzle and the second spray nozzle are alternately arranged with a preset interval therebetween in a lengthwise direction of the deposition source.

4. The display device manufacturing apparatus of claim 2, wherein,
in the nozzle unit,
the first spray nozzle and the second spray nozzle are arranged parallel to each other in a width direction of the deposition source.

5. The display device manufacturing apparatus of claim 2, wherein
the first spray nozzle has
an inclination angle ranging from about 30° to about 75° directed toward the front portion in a lengthwise direction of the deposition source.

6. The display device manufacturing apparatus of claim 2, wherein
the second spray nozzle has
an inclination angle ranging from about 30° to about 75° directed toward the rear portion in a lengthwise direction of the deposition source.

7. The display device manufacturing apparatus of claim 1, wherein
the nozzle unit has
an inclination ranging from about 30° to about 75° directed toward the substrate on a surface of the deposition source.

8. The display device manufacturing apparatus of claim 1, wherein
the nozzle unit
deposits the deposition material on an area of the substrate, which is disposed adjacent to the second outer area, from the nozzle arranged in the first outer area, and
deposits the deposition material on an area of the substrate, which is disposed adjacent to the first outer area, from the nozzle arranged in the second outer area.

9. The display device manufacturing apparatus of claim 1, wherein
the deposition source has a non-spray area in the central area.

10. The display device manufacturing apparatus of claim 1, wherein
the nozzle unit
deposits the deposition material on the substrate in an inclined direction directed between a lengthwise direction and a width direction of the substrate from a plurality of nozzles.

11. The display device manufacturing apparatus of claim 1, wherein
the deposition source
has the central area disposed above where the substrate is arranged and linearly moves along a lengthwise direction of the substrate.

12. A display device manufacturing method comprising:
preparing a deposition source having a central area, and a nozzle unit disposed on each of a first outer area and a second outer area arranged on both sides of the central area;
placing a substrate above the central area; and
depositing a deposition material onto the substrate while moving the deposition source.

13. The display device manufacturing method of claim 12, wherein
the nozzle unit has an inclination directed toward the central area.

14. The display device manufacturing method of claim 12, wherein
the deposition source has a non-spray area in the central area.

15. The display device manufacturing method of claim 12, wherein
the deposition material is deposited on an area of the substrate, which is disposed adjacent to the second outer area, from the nozzle unit arranged in the first outer area, and
the deposition material is deposited on an area of the substrate, which is disposed adjacent to the first outer area, from the nozzle unit arranged in the second outer area.

16. The display device manufacturing method of claim 12, wherein
the nozzle unit includes a first spray nozzle having an inclination directed toward a front portion of a direction in which the deposition source moves, and a second spray nozzle having an inclination directed toward a rear portion of the direction in which the deposition source moved.

17. The display device manufacturing method of claim 16, wherein
the first spray nozzle has an inclination angle ranging from about 30° to about 75° directed toward the front portion in the lengthwise direction of the deposition source.

18. The display device manufacturing method of claim 16, wherein
the second spray nozzle has an inclination angle ranging from about 30° to about 75° directed toward the rear portion in the lengthwise direction of the deposition source.

19. The display device manufacturing method of claim 12, wherein
a plurality of nozzles in the nozzle unit deposits the deposition material on the substrate in an inclined direction directed between the lengthwise direction and the width direction of the substrate.

20. An electronic device, comprising:
a display device, wherein the display device is manufactured via a display device manufacturing method, wherein the display device manufacturing method comprises,
preparing a deposition source having a central area, and a nozzle unit disposed on each of a first outer area and a second outer area arranged on both sides of the central area;
placing a substrate above the central area; and
depositing a deposition material onto the substrate while moving the deposition source.
